(19) United States
(12) Patent Application Publication
(10) Pub. No.: US 2026/0318737 A1
(43) Pub. Date: Oct. 15, 2026

(54) SUPERCONDUCTING CIRCUIT FOR DETECTING SINGLE PHOTONS

(71) Applicants: THE REGENTS OF THE UNIVERSITY OF COLORADO, A BODY CORPORATE, Denver, CO (US); GOVERNMENT OF THE UNITED STATES OF AMERICA, AS REPRESENTED BY THE SECRETARY OF COMMERCE, GAITHERSBURG, MD (US)

(72) Inventors: JEFFREY MICHAEL SHAINLINE, Boulder, CO (US); ADAM MCCAUGHAN, Denver, CO (US); SAEED KHAN, Boulder, CO (US); BRYCE PRIMAVERA, Louisville, CO (US)

(21) Appl. No.: 19/485,585

(22) PCT Filed: May 17, 2024
(86) PCT No.: PCT/US2024/030058

§ 371 Date: Nov. 18, 2025

Related U.S. Application Data
(60) Provisional application No. 63/467,534, filed on May 18, 2023.
(60) Provisional application No. 63/467,542, filed on May 18, 2023.

(51) Int. Cl. G01J 1/44; H03K 17/687

(52) U.S. Cl. CPC G01J 1/44; H03K 17/6872; G01J 2001/442

(57) ABSTRACT

A superconducting circuit for detecting single photons includes a detector sub-circuit having a superconducting branch and a bypass branch in parallel with the superconducting branch. The superconducting branch includes a superconducting nanowire single-photon detector (SNSPD). The detector sub-circuit outputs a photon-indicating signal in response to the SNSPD absorbing a single photon. The superconducting circuit also includes a fluxon generator coupled to the bypass branch of the detector sub-circuit. The fluxon generator generates one or more singleflux quantum (SFQ) pulses in response to receiving the photon-indicating signal. The superconducting circuit also includes an integrator loop that includes the fluxon generator. The integrator loop increments an integrator current flowing through the integrator loop by an incremental current for each of the one or more SFQ pulses generated by the fluxon generator. The superconducting circuit also includes a readout sub-circuit that generates an output voltage that is based on the integrator

### RELATED APPLICATIONS

This application claims priority to U.S. Provisional Patent Application No. 63/467,534, filed on May 18, 2023, and U.S. Provisional Patent Application No. 63/467,542, filed on May 18, 2023. Each of these applications is incorporated herein by reference in its entirety.

### STATEMENT REGARDING FEDERALLY SPONSORED RESEARCH OR DEVELOPMENT

This invention was made with government support under grant numbers HR0011149863 and HR0011151332 awarded by the Defense Advanced Research Projects Agency. The government has certain rights in the invention.

### BACKGROUND

A superconducting nanowire single-photon detector (SNSPD) is a type of optical detector that uses a superconducting nanowire to detect single photons in the optical and infrared regions of the electromagnetic spectrum.

### SUMMARY

The present embodiments include superconducting single-photon detectors that integrate signals locally at each pixel of a multi-pixel array. This capability is realized by the monolithic integration of superconducting-nanowire single-photon detectors with Josephson electronics. The motivation is to realize superconducting sensor elements with integrating capabilities similar to their CMOS-sensor counterparts.

The superconducting circuits of the present embodiments may operate in several modes. First, it is shown that photons can be counted individually, with each detection event adding an identical amount of supercurrent to an integrating element (e.g., an integrating loop). Second, an active gain control option is demonstrated; in this operating mode, the signal added per detection event is dynamically adjusted to account for variable light conditions. Additionally, the pixels may either retain their signals indefinitely to record all counts incurred over an integration period (referred to “photon-counting mode”), or the pixels can record a fading signal of detection events within a decay time constant (referred to as “power-meter mode”). Some embodiments include additional semiconductor readout circuitry to realize scalable, large-format sensor arrays of superconducting single-photon detectors compatible with CMOS array readout architectures.

In embodiments, a superconducting circuit for detecting single photons includes a detector sub-circuit having a superconducting branch and a bypass branch in parallel with the superconducting branch. The superconducting branch includes a superconducting nanowire single-photon detector (SNSPD). The detector sub-circuit is configured to output a photon-indicating signal in response to the SNSPD absorbing a single photon. The superconducting circuit also includes a fluxon generator coupled to the bypass branch of the detector sub-circuit. The fluxon generator is configured to generate one or more single-flux quantum (SFQ) pulses in response to receiving the photon-indicating signal from the detector sub-circuit. The superconducting circuit also includes an integrator loop that includes the fluxon generator. The integrator loop is configured to increment an integrator current flowing through the integrator loop by an incremental current for each of the one or more SFQ pulses generated by the fluxon generator. The superconducting circuit also includes a readout sub-circuit configured to generate an output voltage that is based on the integrator current.

In embodiments, a method for detecting single photons includes: absorbing a single photon with a SNSPD located in a superconducting branch of a detector sub-circuit; diverting, in response to said absorbing, a bias current from the superconducting branch to a bypass branch of the detector sub-circuit; coupling a photon-indicating signal from the bypass branch to a fluxon generator, the photon-indicating signal being based on the diverted bias current; generating, with the fluxon generator, one or more SFQ pulses in response to the photon-indicating signal; incrementing, by an incremental current for each of the one or more SFQ pulses, an integrator current flowing through an integrator loop that includes the fluxon generator; and generating an output voltage that is based on the integrator current.

### BRIEF DESCRIPTION OF THE FIGURES

FIG. 1A is a schematic diagram of a superconducting single photon counter, in embodiments.

FIG. 1B shows results of a circuit simulation.

FIG. 2 shows microscope images of a fabricated device, in embodiments.

FIGS. 3A-3D shows photon-counter responses for difference input pulse widths. In FIG. 3A, the SQUID bias was 80 μA, which resulted in SFQ operation. In FIG. 3B, the SQUID bias was 90 μA, which resulted in operation outside of the SFQ regime. FIGS. 3C and 3D show statistical analyses of the small and large DI loops, respectively.

FIGS. 4A and 4B show the device response for the current pulse width varying from 100 ns to 6.4 μs, in steps of a factor of two.

FIGS. 5A and 5B show steady-state SQUID voltage as a function of laser pulse frequency at different values of the SFQ-SQUID bias I_{b1}. In FIG. 5A, the DI loop inductance was 250 nH. In FIG. 5B, the DI loop inductance was 500 nH.

FIGS. 6A and 6B are plots comparing readout performance from a standalone and integrated SPD with a 780-nm wavelength laser. In FIG. 6A, a room temperature amplifier with a 50 MHz lower cutoff frequency was used. In FIG. 6B, a room temperature amplifier with a 0.1 MHz lower cutoff frequency was used.

FIG. 7 is a schematic diagram of a circuit that combines single-photon detection, SQUID-based transduction, an integration loop, and CMOS readout, in embodiments.

FIG. 8 is a block diagram of an superconducting-circuit architecture for single-photon detection, counting, and timing, in embodiments.

FIG. 9 is a schematic diagram of a superconducting circuit for detecting and counting single photons, in embodiments.

FIG. 10 is a schematic diagram of a superconducting circuit for detecting and counting single photons, in embodiments.

FIG. 11 is a schematic diagram of a superconducting circuit for detecting and counting single photons, in embodiments.

FIG. 12 is a schematic diagram of a superconducting circuit for detecting and counting single photons, in embodiments.

FIG. 13 is a schematic diagram of a superconducting circuit that both detects single photons and records their arrival times, in embodiments.

FIG. 14 is a plot of signal size versus tₚₕ/Δtᵣₐₘₚ, as simulated for the superconducting circuit of FIG. 13.

FIG. 15 is a schematic diagram of a superconducting circuit that both detects single photons and records their arrival times, in embodiments.

FIG. 16 is a schematic diagram of a superconducting circuit that both detects single photons and records their arrival times, in embodiments.

### DETAILED DESCRIPTION

### Introduction

Superconducting-nanowire single-photon detectors (SPDs) are gaining maturity with reported system detection efficiencies greater than 98% and timing jitter below 3 ps. These devices can detect single quanta of radiation, and the same basic device concept can be used from the UV to mid-IR, with recent demonstrations showing high efficiency at wavelengths up to 10 μm. SPDs have very low dark counts and may be fabricated with a simple process into relatively large (e.g., 400 kilopixel) arrays. Large arrays are desirable for many purposes such as imaging and spectroscopy with applications including astronomy, semiconductor circuit metrology, and biomedical imaging.

However, readout of large arrays remains a key impediment to adoption in deployed systems. When an SPD detects a photon, the bias current is diverted from the wire. Room temperature amplifiers and digital electronics are typically used to read out the current pulses from each detector independently. This approach often requires large numbers of coaxial cables inside the cryostat and extensive room-temperature electronics, limiting scaling to larger arrays. Additionally, when detecting photons deeper in the mid-IR, the energy of the photons decreases, necessitating narrower nanowires, which carry less current and provide smaller pulses for detection. Directly amplifying and measuring each diverted current pulse is not an ideal measurement technique for large arrays of SPDs. For the largest arrays demonstrated to date, multiplexed readout lines are employed that limit total system count rates, and the means of encoding SPD detection events onto the readout line requires large SPD currents, which makes operation with mid-infrared SPDs difficult.

Several approaches to readout of SPDs involve the transduction of pulses from the SPD to supercurrent using superconducting electronic circuitry. Example approaches include circuitry based on nanowires or Josephson junctions (JJs). When using JJs, it is possible to leverage superconducting quantum interference devices (SQUIDs) as sensitive flux-to-voltage transducers or to make use of digital processing with single-flux-quantum circuits or adiabatic quantum flux parametron circuits. Most of these efforts using JJs to readout SPDs have employed separate chips for the sensors and the readout electronics with wire bonds between the specialized die; two recent demonstrations have accomplished monolithic integration of SPDs with JJs.

The present embodiments include an approach to large-scale SPD array readout that makes use of SPDs integrated with JJs and SQUIDs to introduce a technique of photon-count integration akin to CMOS cameras. Demonstrated herein are single-photon integrating pixels suitable for this approach, where the history of photon detection events is locally stored at each pixel, analogous to charge accumulation in CMOS sensors. Circuits performing these functions may be achieved through the monolithic integration of SPDs with JJs. In these circuits, an SPD works in conjunction with JJ circuits to transduce photon detection events into current that can be stored indefinitely in a superconducting loop at each pixel. This approach decouples detection events from the readout process. Low-noise readout may be accomplished through a measurement duration that is not limited by the temporal extent of the SPD current pulse. This measurement can be accomplished with MOSFET circuits that transduce the integrated current signal to charge on a capacitor. At that point, the readout proceeds exactly as in a CMOS sensor array. SPD-JJ integration circumvents the small SPD current signal in the mid-IR regime, as explained later. Further integration with MOSFETs enables a low-noise, scalable readout framework that never misses an SPD count, only sends the required information to room temperature, and transduces low-voltage superconductor signals to semiconductor-level voltages to be processed by conventional silicon electronics. This integrated approach leverages the best attributes of superconducting sensors with the convenience and fieldability of semiconductor array readout concepts. While monolithic integration appears feasible and should be pursued, the superconducting circuits could also be bump bonded to CMOS readout circuits, which would allow the complete circuits to be fabricated with existing processes.

### Photon Counter Circuit

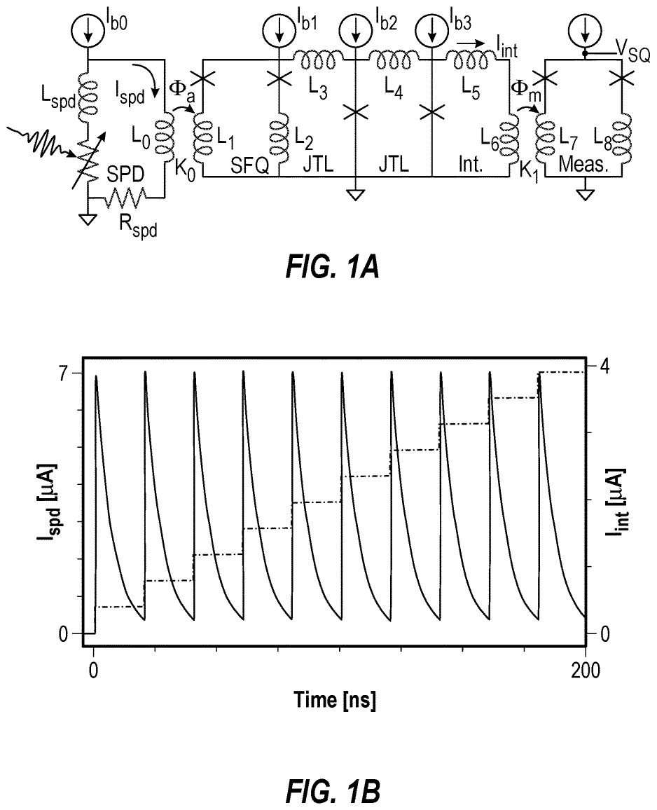

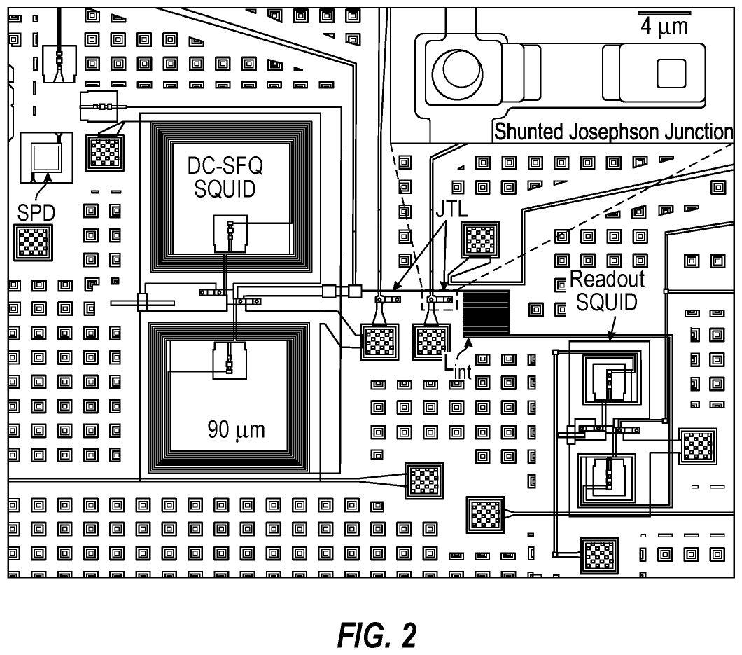

The single-photon integrating pixel concept demonstrated here is shown in FIGS. 1A and 1B. A detection event from the SPD is converted into a single-flux quantum (SFQ) through an inductively-coupled DC-SFQ converter. The SFQ pulse leaving the DC-SFQ converter then propagates down a short Josephson transmission line (JTL) and is added to an integration loop (Int.) at the pixel. The Josephson transmission line comprises two junctions between the DC-SFQ converter and the integration loop, as shown in FIG. 1A. One benefit of this approach is that the input to the DC-SFQ converter is not current, but rather magnetic flux, which is the product of current and mutual inductance. The mutual inductance between the SPD and the DC-SFQ converter can be quite large, limited primarily by space, enabling even small SPD pulses to generate SFQ pulses. SPD output currents can be as small as 1 μA when detecting long-wavelength photons in the mid-IR. The price is area, with the DC-SFQ converter receiving the SPD pulse requiring an area of 30 μm×30 μm. Still, a megapixel array would fit on a 3 cm×3 cm sensor chip. Therefore, by integrating JJs with SPDs it is possible to overcome the limitation of small current signals and provide local integration of the signal at each pixel. Timing information is retained at the level of a 10 kHz frame rate (100 μs) as opposed to the sub-ns jitter of the detection event. The retained temporal information is more than sufficient for imaging and some spectroscopic applications. By separating photon detection and integrated signal measurement, it is possible to integrate photon counts for as long as desired and separately measure the accumulated signal for as long as necessary to realize noiseless readout.

FIG. 1A is a schematic diagram of a superconducting single photon counter. Parameters used in the simulation and design are the same except for R_{spd}, which was increased from 12.375 Ω to 123.75 Ω in the simulation to reduce simulation time. The rest of the parameters were L_{spd}=825 nH, L₀=3.1 nH, L₁=12.7 pH, L₂=1.1 pH, L₃=L₄=10.34 pH, L₅=5.3 nH, L₆=0.18 nH, L₇=9.36 pH, L₈=0.8pH. Mutual inductance couplings were K₀=0.5 and K₁=0.25. The critical current (I_{c}) of all Josephson Junctions was 100 μA. The simulation bias currents were I_{b0}=10 μA, I_{b1}=140 μA, I_{b2}=I_{b3}=70 μA. FIG. 1B shows results of the circuit simulation. The solid curve is the current diverted from the SPD (I_{spd}), which is plotted relative to the left y-axis. The dot-dashed curve is the current being integrated in response to each SPD pulse (Iᵢₙₜ), which is plotted relative to the right y-axis.

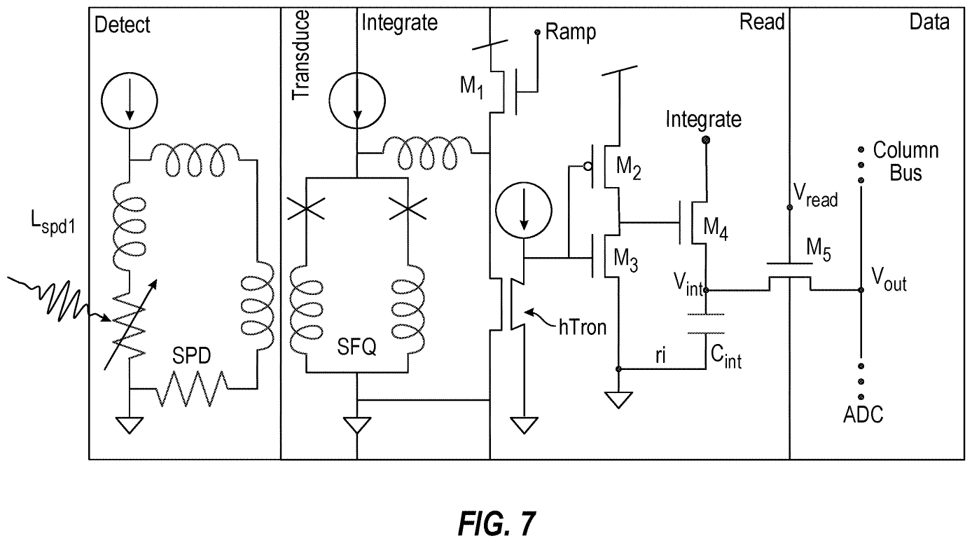

The circuit in FIG. 1A involves an SPD, a DC-SFQ converter (topologically equivalent to a DC SQUID), a Josephson transmission line, an integration loop that stores the pulses, and a readout component. A readout SQUID is used as the readout component, but a row-column bus architecture identical to CMOS sensor arrays may alternatively be used (see FIG. 7). The first step in the circuit operation is the detection of a photon by the SPD. When a photon that is absorbed by the SPD breaks superconductivity and causes a resistive hot spot, the bias current I_{b0} will be diverted from the SPD into a transformer coupled to the SPD-to-SFQ SQUID, labelled as SFQ in FIG. 1A. Simulation results of the SPD current pulses, I_{spd}, are shown in FIG. 1B by the solid curve.

The next step is the transduction of each detected photon into an individual fluxon. A fluxon is a quantum of magnetic flux denoted by and equal to Φ≡h/2e~2 mV·ps. Each fluxon generated by the SPD-SFQ transducer circuit propagates through a Josephson transmission line and is stored as current in an integration loop. In the present case, the SPD provides flux input after each photon detection event, producing a discrete amount of supercurrent that is stored in an inductive loop after passing through the Josephson transmission line, which we refer to as the detector integration (DI) loop. In response to a single photon detection event, the integrated current can either be in the form of a single flux quantum or the form of several flux-quantum pulses. The former case results in digital operation in which each photon detection event produces an identical current signal; this case is referred to as SPD-SFQ operation or digital mode. In this case, the amount of current added to the loop per photon detection is Φ₀/L, where L is the loop inductance. Current in the integration loop is shown by the dot-dashed curve in FIG. 1B. In the latter case, each photon leads to an analog signal that can be adjusted with a control bias (I_{b1}). The main advantage of the digital mode of operation is that it is conducive to zero-noise operation and less dependent on circuit bias current I_{b1}. There is a one-to-one correspondence between the number of detected photons and stored fluxons. This results in a near-perfect linear relationship between photon count and integrated current. The amplitude of added signal accumulated with each photon detection event is identical across an extremely broad range. With this mode of operation, 1024 photon pulses can be detected with exact linear response across all pulses. On the other hand, the advantage of the analog mode is that the amplitude of the signal can be adapted by adjusting the bias current I_{b1}, which enables gain control for adjustable performance depending on the light level. The same hardware infrastructure supports both modes of operation.

In either the analog or digital case, the generated current is stored in the integration loop where the signals from repeated photon-detection events are summed. With the integration loop there are again two modes of operation. In one mode, the loop has zero resistance and the signal is stored with no decay, as shown in FIG. 1B. In this mode of operation, the current stored in the loop immediately preceding a read event is proportional to the total number of photons that have been detected in that integrate-read cycle. In the second mode, the integration loop has a finite resistance and the integrated signal leaks with a rate given by the loop τ=L/r time constant. The signal stored in the pixel is proportional to the rate of photon detection events in the preceding time interval of order τ. In this mode of operation, no external signal is required to reset the state of the loop. This is a leaky integrator wherein the signal is proportional to the recent rate of photon detection events, so in this mode the sensor is a power meter (assuming incident photons of uniform energy). The exact same pixel may be used in either power or energy integration mode with the inclusion of a simple resistive element. While a single pixel is demonstrated, the readout concept will scale to large arrays (e.g., hundreds of thousands of pixels, or more).

For other applications that require precise timing information, similar circuits may be used. With minor modifications, each pixel may be engineered to store a current proportional to the time of arrival of a photon relative to a clock. This approach leverages the high switching speed of JJs to potentially store timing information with picosecond resolution. Readout proceeds identically to the case of the photon-counting pixels presented here. More details about these photon timing circuits is presented below.

### Fabrication

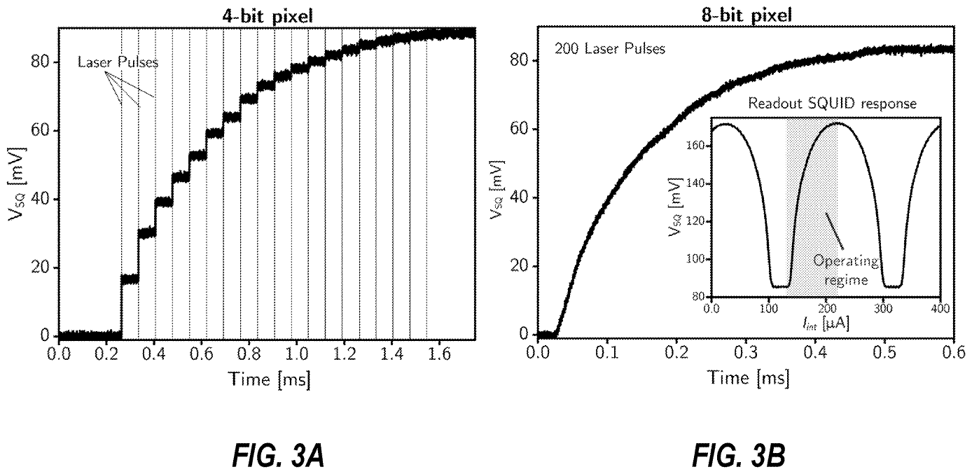

The fabrication consists of fifteen mask layers. Electron-beam lithography was used for the SPD step, while all other patterning was accomplished with photolithography using a 365 nm i-line stepper. In brief, a 40-nm Nb wiring layer for contact to the SPDs was patterned using a liftoff process. Liftoff was used to avoid a vertical edge and provide a gradual, sloping contact for the thin film used for the SPDs. The SPDs were formed from a 4.1 nm thick MoSi film, which was sputtered after the Nb contact layer. The MoSi was patterned into a detector meander using electron-beam lithography to realize wire widths around 200 nm. An interlayer dielectric of SiO₂ insulates the SPD layer from a Nb ground plane above it. The JJ trilayer stack (Nb-aSi—Nb) is then deposited and patterned above the ground plane, with another SiO₂ insulator in between. PdAu resistors are patterned and deposited with liftoff to form the JJ shunt resistors. An additional low-resistance Au layer was used to make resistors with small values and therefore long attainable leak time constants in the integrating loops used in power-meter mode, as described in the section below titled “Experimental Characterization.” An additional top insulator sealed the structures. All layers were connected with Nb vias through the insulators. Microscope images of the fabricated device are shown in FIG. 2.

Roughly 12 devices from this wafer were tested, and all operated close to designed performance. There were no failures due to fabrication issues. The JJ cross-wafer I_{c} variation was around ±20% from the center to the edge of the 76.2 mm wafer, with the nominal value residing in a ring of half the wafer radius. Such variation is typical for this process and this sputtering tool.

A major challenge for this SPD readout concept is to reduce the size of the readout circuitry while achieving a high SPD fill factor. Two fabrication improvements will enable circuit size reduction. First, lithography with higher resolution for the wiring layers would enable reduction of the size of the input coil into the transduction SQUID by at least a factor of 100 by reducing the wire width from 1 μm to 200 nm and wire thickness from 200 nm to 20 nm. Second, by utilizing a damascene process with planarization between each layer, the components of the circuit can be stacked vertically. This would significantly reduce the overall footprint of the circuit and enable the SPD meander to be on the top layer, spread above the transduction and readout circuitry below. Such a fabrication process would be the default for a mature foundry, but the unplanarized process is much more tractable in NIST's research cleanroom.

### Experimental Characterization

Measurements were performed at 2.3 K in a closed-cycle Gifford-McMahon cryostat. The chip was flood illuminated by a fiber-coupled, 780 nm pulsed laser source. The availability of an inexpensive, pulsed laser source was the only reason this wavelength was used; the circuit concept is applicable for SPDs from the UV to the mid-IR. The laser pulse width was approximately 480 ps, while the SPD recovery time was approximately 37.5 ns. Therefore, multiple detection events per pulse were unlikely. The maximum voltage from the readout SQUID (V_{SQ}) was approximately 10 V and a room-temperature amplifier with 60 dB voltage gain was used for measurements.

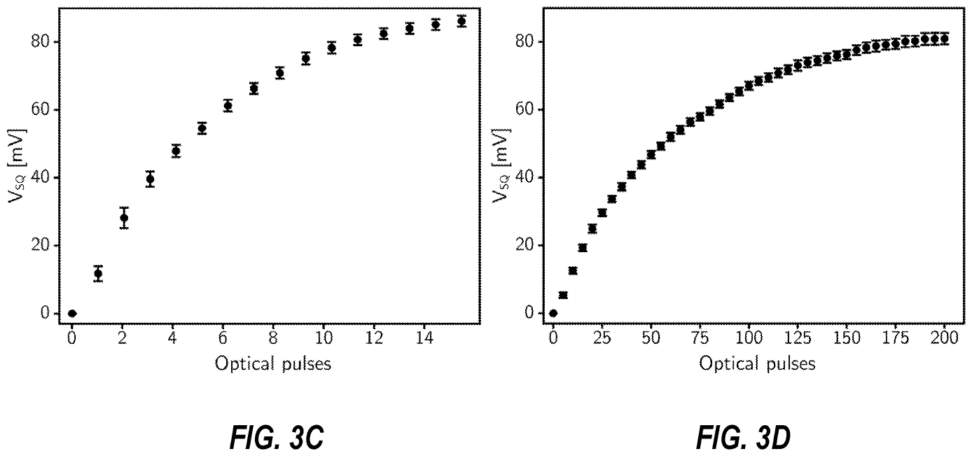

FIGS. 3A and 3B show the voltage V_{sq} across the SQUID as a function of time while optical pulses are directed at the SPD at a fixed rate. In FIG. 3A, the integration loop inductance is 330 pH, chosen to store 16 pulses (4 bits), while that of FIG. 3B is 5.3 nH, chosen to store 256 pulses (8 bits). Discrete steps are evident with each laser pulse in FIG. 3A as a fluxon enters the integration loop. These are identical fluxon pulses, but here the measured response is nonlinear because it is convoluted with the response of the readout SQUID (the readout SQUID response is shown in the inset of FIG. 3B). The same discrete steps are present in the response of FIG. 3B but are not discernible as they are smaller than the noise, which in this case is due to line noise coupled from our cryostat compressor to our measurement electronics. The readout scheme described below in the Section titled “Summary and Discussion” eliminates both this non-linearity and noise.

FIGS. 3C and 3D show statistical analyses of the small and large DI loops, respectively. The data points are the SQUID voltage averaged over 1000 independently measured traces. Each trace was taken after the number of photonic pulses indicated on the x-axis. The error bars give the standard deviation calculated from the 1000 traces. After each trace was generated and recorded, the current in the integration loop was erased by driving current through a PdAu resistor, fabricated in close vicinity to the inductor in the DI loop, Lᵢₙₜ. To reset the state of the DI loop, a 10 mA current was applied to the resistor, which heated the inductor, broke superconductivity, and purged the integrated current in the loop.

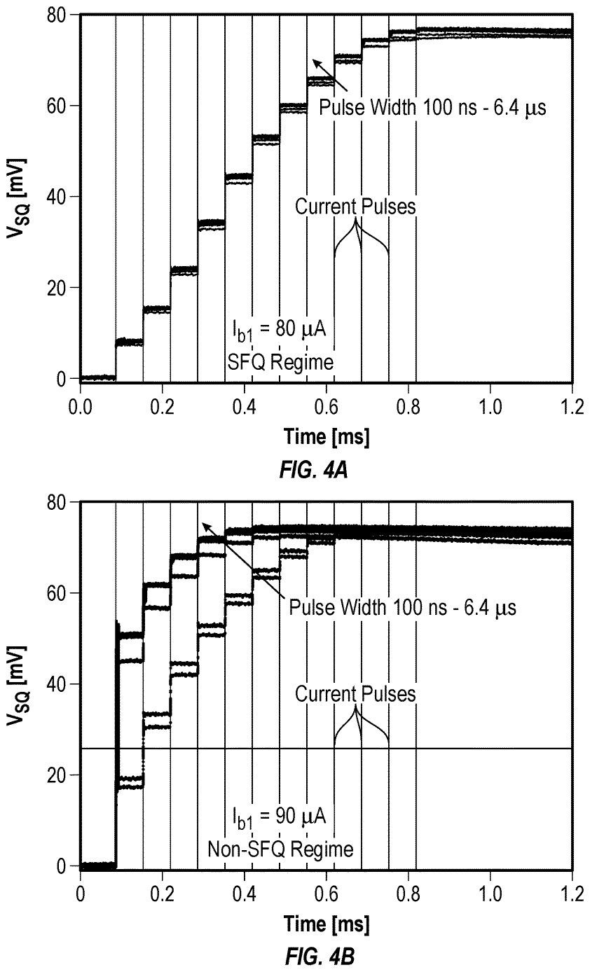

To make sure the photon counters are working in SPD-SFQ mode in FIGS. 3A and 3B, the SPD was driven with current pulses that exceeded the switching current instead of relying on optical pulses. In this way the width of the input pulses could be changed. An SPD-SFQ converter should output only one SFQ pulse for each input pulse, regardless of the duration of the input pulse. FIGS. 4A and 4B show the device response for the current pulse width varying from 100 ns to 6.4 μs, in steps of a factor of two (geometrically spaced, i.e., 100 ns, 200 ns, 400 ns, 800 ns, 1.6 μs, 3.2 μs, 6.4 μs). No significant change in the output of the device is observed. The inductor in the integration loop can hold only around 16 SFQ pulses before it saturates. Because it does not saturate at a lower number of pulses when driven with a larger pulse width, we conclude the device is operating in the SPD-SFQ regime. In FIGS. 3B and 4B, the bias current I_{b1} to the SFQ SQUID was increased from 80 μA to 90 μA, thus moving the circuit outside the SPD-SFQ regime. In this case, the integration loop saturates with fewer pulses as the pulse width is increased. Furthermore, the readout SQUID voltage step should be less than ~10 mV for a single SFQ pulse, considering the inductance of the integration loop, room temperature amplification, and operating point on the readout SQUID response curve. Hence, at around 80 μA SFQ-SQUID bias, the device is working in the desired SPD-SFQ mode, while by 90 μA SFQ-SQUID bias it is no longer producing exactly one fluxon per photon detection event. In FIG. 4B, the slight decrease of current with time is due to a DC block filter.

In addition to the digital SPD-SFQ operation just described, we have conducted measurements of similar circuits operated in analog, power-meter mode. For this demonstration, a slightly different circuit was used in which the initial transduction SQUID (referred to as SPD-SFQ up to this point) had more symmetric inductances, compared to the counter (L₁=9.2 pH and L₂=5.4 pH in FIG. 1A). This more symmetric design is employed to implement the analog as opposed to digital transduction operation. The modified circuit also included a resistor in the integration loop, providing a leak rate. Thus, the circuit used in this part of the study is an analog power meter as opposed to the digital photon counter demonstrated in FIGS. 3A-3D. In this mode, the initial transduction SQUID produces a stream of fluxons with each detection event. The number of fluxons generated with each detection event is determined by the bias current I_{b1}, which provides a control knob to adjust the response of the pixel based on the light level. The decay time here is around 6.25 μs, which is determined by the L/R decay time of the integration loop. For sufficiently long pulse trains at a given frequency, the device reaches a steady state that can be tuned with I_{b1}.

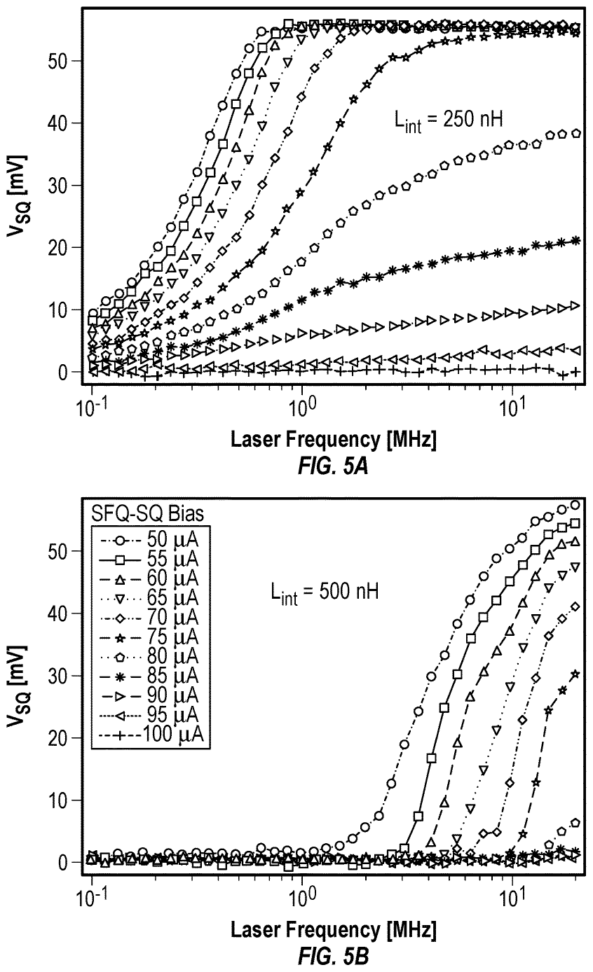

FIGS. 5A and 5B show the voltage on the readout SQUID as a function of the frequency of input photonic pulses. The different traces correspond to different values of I_{b1}, and this dynamically variable control parameter may be used to adjust the response to keep the pixel in a useful dynamic range. For a given value of I_{b1} and a given input rate of photons, the pixel will reach a different steady-state value, which may then be used to determine the incident light flux through a calibration procedure. FIGS. 5A and 5B show the measured SQUID voltage as a function of the incident pulse rate for values of the bias current I_{b1} from 50 μA to 100 μA, demonstrating tuning across several orders of magnitude in incident photon flux. These are the transfer functions that can be used to determine the rate of incident photons. FIG. 5A shows data for the device with 250 nH inductance in the DI loop while FIG. 5B has an inductance of 500 nH. It can be seen that with this range of input signal rates and integration-loop leak rate, the dynamic range of the smaller capacity loop is better matched to the signal.

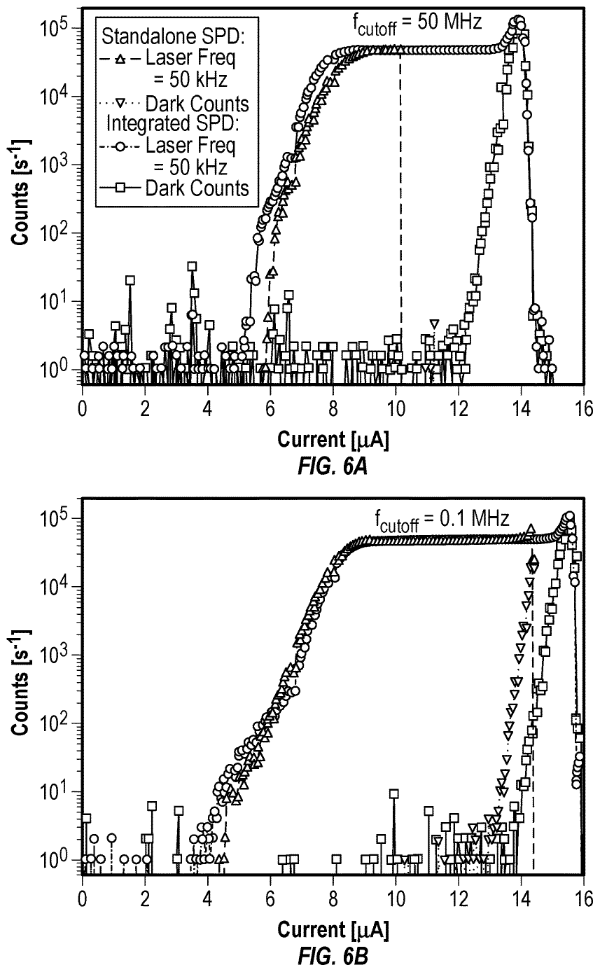

During experimentation, the inventors discovered that reading SPD pulses through Josephson electronics may reduce the effect of amplifier noise compared to standalone SPD readout. In the standalone SPD readout scheme, the SPD is connected to an amplifier through a bias tee. If there are high-frequency reflections from the amplifier, they will pass though the bias tee and affect the SPD. This amplifier noise lowers the SPD operating range and limits the device operation to a smaller plateau. On the other hand, in the integrated SPD scheme described herein, the SPD is not connected to a bias tee. It is well isolated from the amplifier though two superconductor SQUID transformers, leading to a more stable SPD bias current. FIGS. 6A and 6B show the count rate versus SPD bias current for both a standalone and an integrated SPD that were fabricated on the same wafer, with the same geometry, and located in close proximity on the chip. For the integrated SPD, the power-meter device was used with a leak in the integration loop. For sufficiently low laser frequency, the decay time in the DI loop is smaller than the separation of laser pulses. Therefore, individual voltage pulses were discernable and could be counted using a commercial pulse counter. A laser pulse frequency of 50 kHz was used for both the standalone and integrated SPDs. In FIG. 6A, the room temperature amplifier used had a lower cutoff frequency of 50 MHz, and therefore frequencies below 50 MHz are expected to reflect from the amplifier. This lowers the operating range of the standalone SPD. On the other hand, the integrated SPD is not affected by the reflection, resulting in a factor of three improvement in the width of the plateau region. FIG. 6B shows the same experiment but with an amplifier of 0.1 MHz lower cutoff frequency. Here the plateau region of the standalone SPD comes closer to matching that of the integrated device, yet the integrated SPD still has a larger plateau region by roughly 15%. Regarding dark counts, as seen in FIGS. 6A and 6B, the dark count rate is four orders of magnitude lower than the input pulse rate and had a negligible impact on the measurement.

Throughout this work the inventors did not observe any effects of the light on other parts of the circuit aside from the SPDs. Most wiring was formed from 200 nm-thick Nb, which shows no response to optical illumination at the levels used here. Some large inductors were formed from the same MoSi film as the SPDs, but these inductor meanders were much wider than the SPDs (4 μm as opposed to 200 nm) and were covered by a block of an upper Nb layer.

### Summary and Discussion

The inventors have demonstrated a single-photon-counting pixel that functionally resembles a CMOS sensor pixel. The concept is made possible by the monolithic integration of SPDs with JJs. As shown herein, such pixels can store the signals from several hundred photon-detection events as supercurrent for later readout. This transduction of photons to stored supercurrent relies on the interface between single-photon detectors with DC-SFQ converters. The same basic circuit concept may be used to form a leaky integrator pixel that retains information about the average photon flux incident within a time period set by the leak rate of the integration loop.

In all modes of operation, the signal of interest is supercurrent in an inductor. To achieve scalability matching that of CMOS sensor arrays, the work demonstrated herein may be extended to include a readout architecture that will allow the interrogation of these supercurrents stored in arrays of millions of pixels. While multiple approaches to this technical challenge are possible, further integration of SPDs and JJs with CMOS readout electronics offers a scalable approach to the problem. The integrated current in each pixel may be read out with transistors in an architecture very similar to that of CMOS sensor arrays. To interface superconducting electronics to semiconducting electronics, superconducting signals must be stepped up in voltage. Recent work on superconducting thin-film amplifiers has significantly improved semiconductor-superconductor interfaces. In the superconducting state, these amplifiers have zero resistance and can carry appreciable currents. When switched to the normal state by a current pulse, they transition to a high resistance state within less than a nanosecond, producing the voltage required to switch a MOSFET. These superconducting amplifiers are referred to as hTrons, and the circuit diagram of FIG. 7 shows an hTron interfacing with the integration portion of the pixel to the CMOS readout circuitry. After an integration period, the detector integration loop contains a current proportional to the number of photons that have been detected. At read time, MOSFET M1 provides a ramp that adds to the current through the hTron gate. When M1 begins its ramp, M4 begins delivering a fixed current to the integration capacitor Cᵢₙₜ. When the sum of the integrated current signal and the applied measurement current from M1 reach the hTron gate threshold, a voltage will develop across the hTron channel, switching the gates of M2 and M3, which form an inverter. When this inverter switches, it cuts the voltage to M4, terminating the flow of current to Cᵢₙₜ. After this operation, the charge on Cᵢₙₜ is inversely proportional to the current that was present in the integration loop. This charge now serves as a proxy for the number of photons that were detected during integration. With the desired information represented as charge on a capacitor, the remainder of the readout follows a CMOS sensor array exactly. To read the charge on Cᵢₙₜ, M5 is opened, and the charge is coupled to the column read bus. When the hTron reaches its threshold, the current in the detector integration loop is erased, so the measurement of the state of the loop is destructive, and integration begins again with an empty loop.

### Additional Embodiments

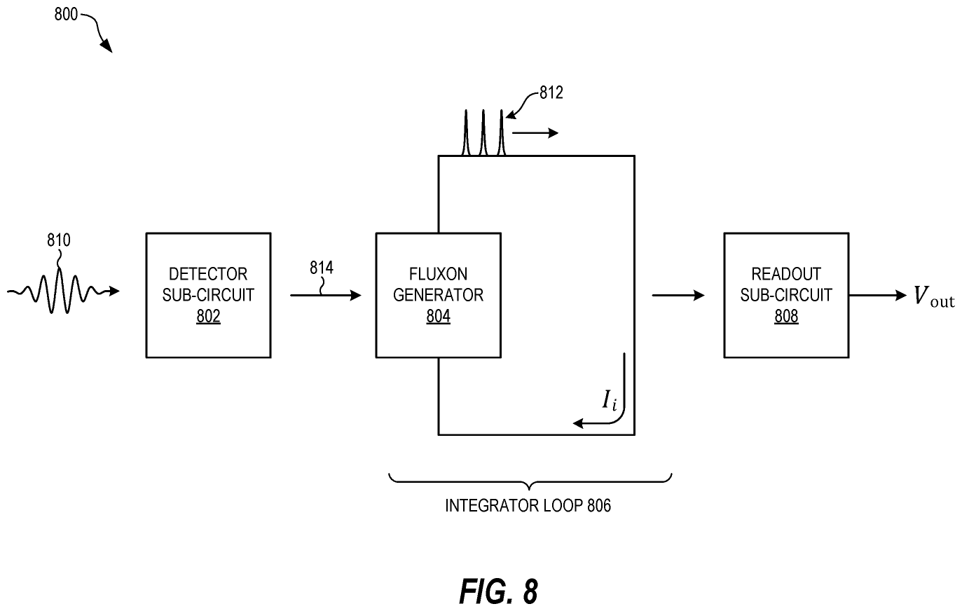

FIG. 8 is a block diagram of an superconducting-circuit architecture 800 for single-photon detection, counting, and timing, in accordance with the present embodiments. The architecture 800 includes a detector sub-circuit 802 that detects a single photon 810. In response to detecting the single photon 810, the detector sub-circuit 802 outputs a photon-indicating signal 814. The architecture 800 also includes a fluxon generator 804 that generates one or more single-flux quantum (SFQ) pulses 812 in response to receiving the photon-indicating signal 814. Thus, the photon-indicating signal 814 may be thought of as a trigger signal that controls the fluxon generator 804 to generate the one or more SFQ pulses 812.

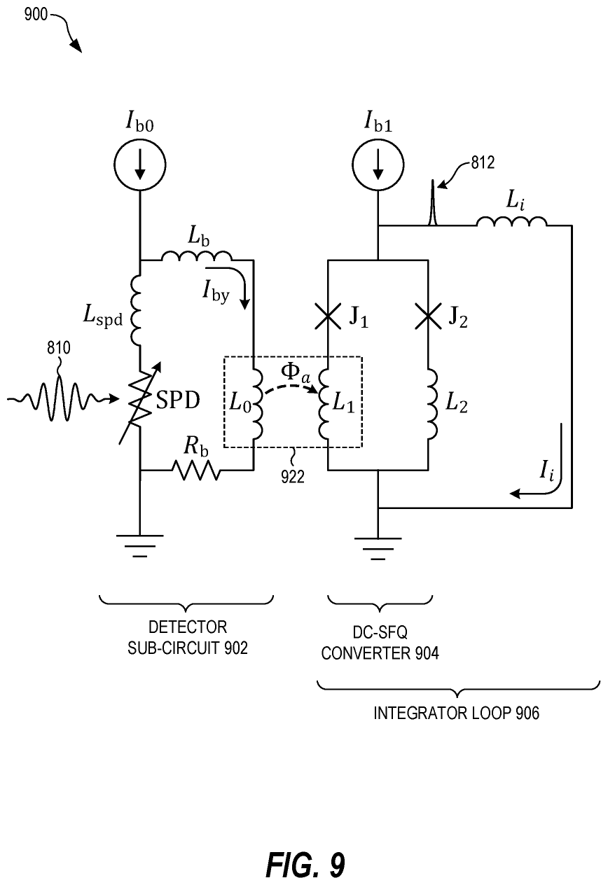

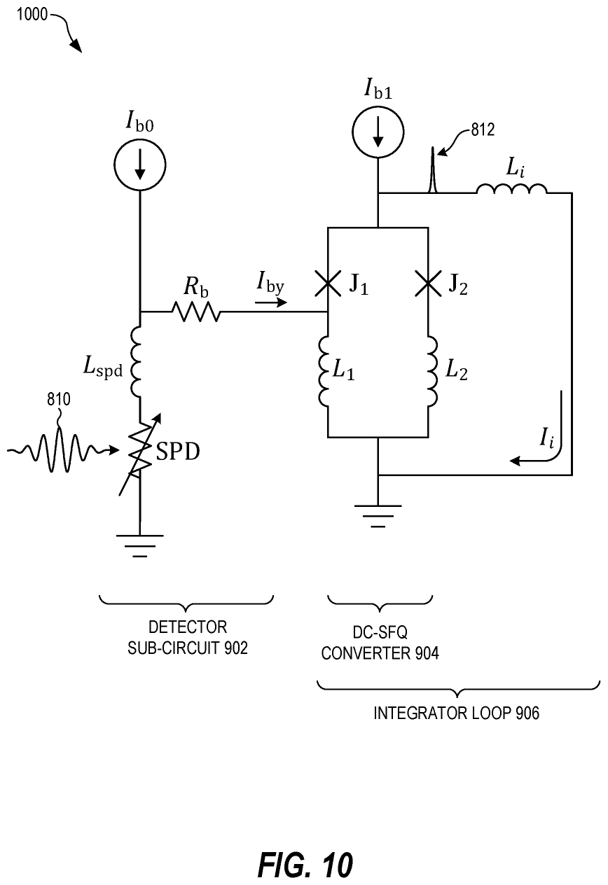

As described in more detail below, examples of the fluxon generator 804 include various types of superconducting quantum interference devices (SQUIDs) and direct-current-to-SFQ (DC-SFQ) converters. The photon-indicating signal 814 may be inductively coupled between the detector sub-circuit 802 and fluxon generator 804 (e.g., via a transformer; see transformer 922 in FIG. 9). Alternatively, the photon-indicating signal 814 may be electrically connected between the detector sub-circuit 802 and fluxon generator 804 (see FIG. 10).

The superconducting-circuit architecture 800 also includes an integrator loop 806 that receives the SFQ pulses 812 and stores the SFQ pulses 812 as an integrator supercurrent Iᵢ. Note that the fluxon generator 804 forms part of the integrator loop 806, and thus the integrator supercurrent Iᵢ flows through the fluxon generator 804. The superconducting-circuit architecture 800 also includes a readout sub-circuit 808 that outputs an output voltage Vₒᵤₜ that is based on the integrator supercurrent Iᵢ. Various examples of the readout sub-circuit 808 are shown in more detail below.

FIG. 9 is a schematic diagram of a superconducting circuit 900 for detecting and counting single photons, in accordance with some of the present embodiments. The superconducting circuit 900 uses the superconducting-circuit architecture 800 of FIG. 8. The superconducting circuit 900 includes a detector sub-circuit 902 that is one example of the detector sub-circuit 802 of FIG. 8, a DC-SFQ converter 904 that is one example of the fluxon generator 804 of FIG. 8, and an integrator loop 906 that is one example of the integrator loop 806 of FIG. 8. The DC-SFQ converter 904 forms part of the integrator loop 906.

The detector sub-circuit 902 includes a superconducting nanowire single-photon detector (SPD). The intrinsic inductance of the SPD is represented in FIG. 9 as an inductor L_{spd} that is in series with the variable resistance of the SPD. The SPD is located in a superconducting branch of the detector sub-circuit 902 that connects between (i) a current source that outputs a constant bias current I_{b0} and (ii) ground. The detector sub-circuit 902 also includes a bypass branch that is connected in parallel to the superconducting branch, i.e., between the I_{b0} current source and ground. The bypass branch includes a bypass inductor L_{b}, a primary inductor L₀ of a transformer 922, and a bypass resistor R_{b} that are connected in series.

When the SPD is superconducting, the superconducting branch has no resistance and therefore all of the bias current I_{b0} flows along the superconducting branch and through the SPD. In response to absorbing the single photon 810, a region of the SPD briefly transitions to the normal state, developing a non-zero resistance; this region with finite resistance is known as a hotspot. In this normal state, the superconducting branch has a greater resistance than the bypass branch. In this case, a voltage drop appears across the SPD, which in turn causes part of the bias current I_{b0} to flow along the bypass branch as a bypass current I_{by}. The primary inductor L₀ generates a magnetic flux Φₐ in response to the bypass current I_{by} flowing therethrough. When the SPD returns to the superconducting state, the bypass current I_{by} stops and the bias current I_{b0} returns to flowing along the superconducting branch. The inductor L_{b} and resistor Rₛ establish a time constant at which the bypass current I_{by} decays.

The DC-SFQ converter 904 has the same topology as a SQUID but is configured differently. Specifically, the DC-SFQ converter 904 includes a first branch containing a first Josephson junction J₁ and a secondary inductor L₁ of the transformer 922 in series with each other. The DC-SFQ converter 904 also includes a second branch in parallel to the first branch to create a DC-SFQ converter loop. The second branch includes a second Josephson junction J₂ and an inductor L₂ in series with each other.

The secondary inductor L₁, in response to receiving the magnetic flux Φₐ from the primary inductor L₀, creates a coupled current in the DC-SFQ converter 904. The magnetic flux Φₐ and coupled current is therefore one example of the photon-indicating signal 814 of FIG. 8. When the coupled current exceeds a converter threshold current, the DC-SFQ converter 904 both (i) injects exactly one SFQ pulse 812 into the integrator loop 906 and (ii) creates exactly one fluxon that propagates around the DC-SFQ converter loop. The integrator loop 906 includes an inductor Lᵢ that low-pass filters the one SFQ pulse 812 to create an incremental current ΔI that is added to an integrator current Iᵢ. Since all components of the integrator loop 806 are superconducting, the integrator current Iᵢ will flow through the integrator loop 806 indefinitely as a supercurrent.

When the flux Φₐ stops and the coupled current falls below the converter threshold current, the DC-SFQ converter 904 is reset by removing the one fluxon from the DC-SFQ converter loop. At this point, the DC-SFQ converter 904 is ready to receive an additional magnetic flux Φₐ, generate an additional SFQ pulse 812, and again increase the integrator current Iᵢ by the incremental current ΔI. The process of adding the incremental current ΔI may continue to increase the integrator current Iᵢ, provided that the integrator current Iᵢ is not reset to zero and provided that the components do not saturate (e.g., the inductor Lᵢ). Thus, for a sequence of n single-photon detection events, the integrator current Iᵢ is proportional to the number n of single photons in the sequence (assuming the integrator current Iᵢ is initially zero). The number n may be several thousand, or more.

FIG. 10 is a schematic diagram of a superconducting circuit 1000 for detecting and counting single photons, in accordance with some of the present embodiments. The superconducting circuit 1000 is similar to the superconducting circuit 900 of FIG. 9 except that the detector sub-circuit 902 is electrically connected to the DC-SFQ converter 904. The resistor R_{b} is located to prevent the bias current I_{b0} from flowing through the DC-SFQ converter 904. Thus, in FIG. 10 the bypass current I_{by} is the photon-indicating signal 814 of FIG. 8. Since there is no inductive coupling between the detector sub-circuit 902 and the DC-SFQ converter 904, the detector sub-circuit 902 excludes the primary inductor L₀ of FIG. 9.

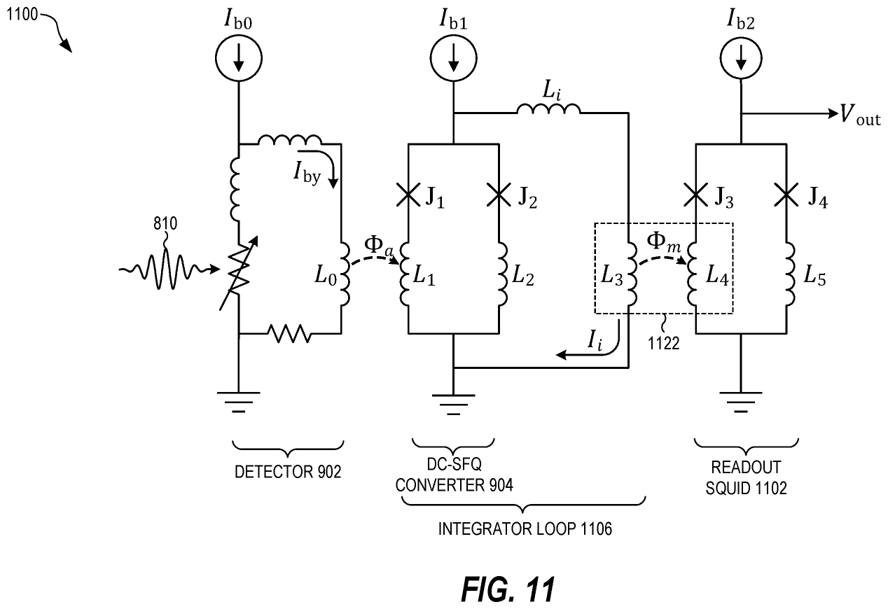

FIG. 11 is a schematic diagram of a superconducting circuit 1100 for detecting and counting single photons, in accordance with some of the present embodiments. The superconducting circuit 1100 uses the superconducting-circuit architecture 800 of FIG. 8. The superconducting circuit 1100 combines the superconducting circuit 900 of FIG. 9 with a readout sub-circuit that generates the output voltage Vₒᵤₜ. In the example of FIG. 11, the readout sub-circuit is a readout SQUID 1102 configured as a magnetic-flux-to-voltage transducer. Magnetic flux Φₘ is coupled to the readout SQUID 1102 via a transformer 1122 having a primary inductor L₃ and a secondary inductor L₄. The superconducting circuit 1100 includes an integrator loop 1106 that is the same as the integrator loop 906 of FIG. 9 except that it includes the primary inductor L₃.

The readout SQUID 1102 has a first branch containing a Josephson junction J₃ and the secondary inductor L₄ in series with each other. The readout SQUID 1102 also includes a second branch in parallel to the first branch. The second branch includes a Josephson junction J₂ and an inductor L₅ in series with each other. One end of the readout SQUID 1102 is driven with a bias current I_{b2} while the other end of the readout SQUID 1102 is grounded.

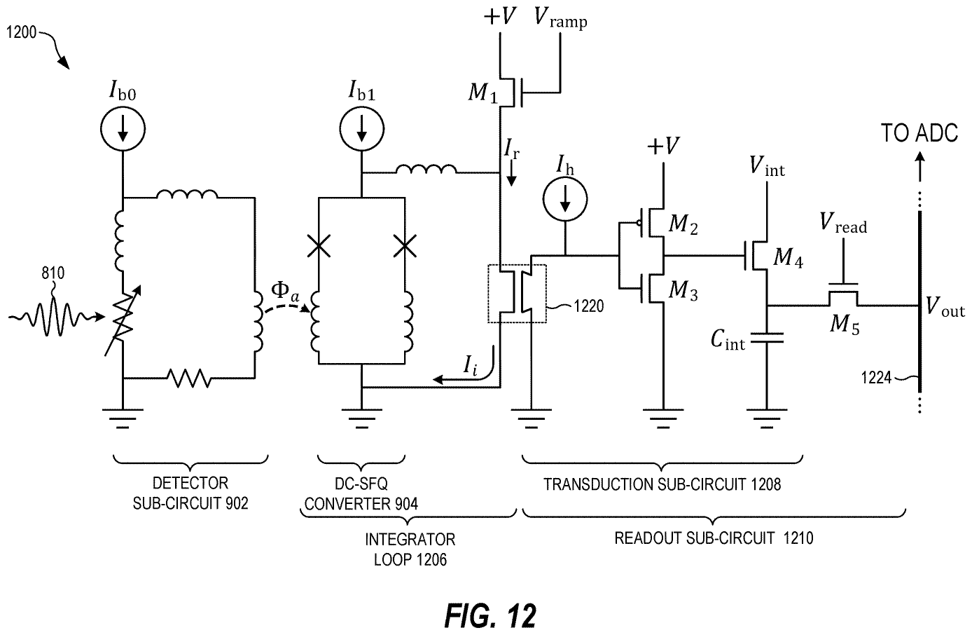

FIG. 12 is a schematic diagram of a superconducting circuit 1200 for detecting and counting single photons, in accordance with some of the present embodiments. The superconducting circuit 1200 uses the superconducting-circuit architecture 800 of FIG. 8. The superconducting circuit 1200 is similar to the superconducting circuit 1100 of FIG. 11 except that the readout SQUID 1102 is replaced with a readout sub-circuit 1210. Thus, FIG. 12 shows an alternative way to measure the integrator current Iᵢ and generate the output voltage Vₒᵤₜ.

The readout sub-circuit 1210 includes a transistor-based transduction sub-circuit 1208 that uses a superconducting switch to measure the integrator current Iᵢ. In FIG. 12 and the following description, the superconducting switch is an hTron 1220. However, another type of superconducting switch may be used without departing from the scope hereof. The hTron 1220 has a two-terminal gate (shown on the left in FIG. 12) that thermally controls a two-terminal channel (shown on the right in FIG. 12). The gate is included in an integrator loop 1206 such that the integrator current Iᵢ flows through the gate. Note that the integrator loop 1206 is the same as the integrator loop 906 of FIG. 9 except that it includes the gate of the hTron 1220.

One end of the channel of the hTron 1220 is connected to a current source that outputs a bias current Iₕ. The other end of the channel is grounded. When the current flowing through the gate of the hTron 1220 exceeds an hTron threshold I_{hT}, the gate transitions from the superconducting state to the normal state. This, in turn causes the channel to also transition from the superconducting state to the normal state, thereby acquiring a finite resistance. Due to the bias current Iₕ flowing through the channel, the voltage outputted by the channel increases due to this change of state. When the gate current drops below the hTron threshold I_{hT}, the gate and channel return back to the superconducting state.

The transduction sub-circuit 1208 also includes an inverter following the hTron 1220. The inverter is shown in FIG. 12 as a p-channel field-effect transistor (FET) M₂ and an n-channel FET M₃ whose gates are tied together. The transduction sub-circuit 1208 also includes a charging switch that is driven by the output of the inverter. The charging switch is shown in FIG. 12 as an n-channel FET M₄ whose drain is connected to a fixed voltage Vᵢₙₜ and whose source is connected to a charging capacitor Cᵢₙₜ. In this configuration, the FET M₄ charges the charging capacitor Cᵢₙₜ while the FET M₄ is turned “on.” Once the gate voltage of the FET M₄ drops below a threshold, the FET M₄ turns “off” and charging of the capacitor Cᵢₙₜ stops. At this point, the voltage across the capacitor Cᵢₙₜ is the output voltage Vₒᵤₜ.

To read the output voltage Vₒᵤₜ, the readout sub-circuit 1210 also includes a readout switch, shown in FIG. 12 as an n-channel FET M₅ whose drain is connected to the charging capacitor Cᵢₙₜ and whose source is connected to a bus 1224. When the FET M₅ is closed, the bus 1224 is charged to the output voltage Vₒᵤₜ. An analog-to-digital converter (ADC) may then be used to digitize the output voltage Vₒᵤₜ.

To see how the output voltage Vₒᵤₜ is proportional to the integrator current Iᵢ, consider a linearly ramped current Iᵣ(t)=αt that is injected into the integrator loop 1206 such that the ramped current Iᵣ(t) flows through the gate of the hTron 1220. Here, a is a constant representing the slope of the ramped current Iᵣ(t). The total current flowing through the gate of the hTron 1220 is therefore the sum of the ramped current Iᵣ(t) and the integrator current Iᵢ. For one ramp, the linearly ramped current Iᵣ(t) starts at zero and reaches a maximum before returning to zero. Thus, one ramp is like one cycle of a sawtooth waveform.

As measured from the beginning of a ramp (i.e., Iᵣ(t₀)=0), the switching time t_{sw} at which the hTron 1220 switches decreases linearly with the integrator current Iᵢ, i.e., a higher integrator current Iᵢ causes the hTron 1220 to switch earlier in the ramp while a lower integrator current Iᵢ causes the hTron 1220 to switch later in the ramp. Mathematically, t_{sw}=(I_{hT}−Iᵢ)/α. Between t₀ and t_{sw}, the capacitor Cᵢₙₜ is charging, and therefore the output voltage Vₒᵤₜ increases linearly with t_{sw}.

To generate the ramped current Iᵣ(t), the transduction sub-circuit 1208 may include a ramp switch having a ramp-switch gate, a ramp-switch source, and a ramp-switch drain. In FIG. 12, the ramp switch is shown as an n-channel FET M₁. In this case, the ramp-switch source is electrically connected to the gate of the superconducting switch (i.e., the hTron 1220), the ramp-switch drain is connected to a power supply (+V) and the ramp-switch gate is driven with a ramped voltage Vᵣₐₘₚ. The FET M₁ acts like a voltage-controlled variable resistor, outputting a current that scales with Vᵣₐₘₚ and therefore changes in time with Vᵣₐₘₚ.

### Photon Timing Circuits

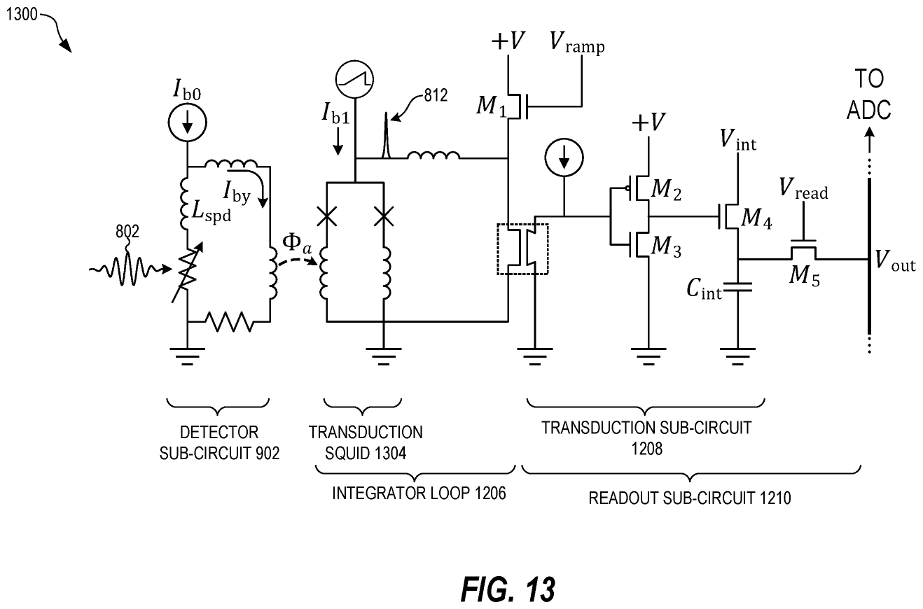

FIG. 13 is a schematic diagram of a superconducting circuit 1300 that both detects single photons and records their arrival times, in accordance with some of the present embodiments. The superconducting circuit 1300 uses the superconducting-circuit architecture 800 of FIG. 8. The superconducting circuit 1300 is similar to the superconducting circuit 1200 of FIG. 12 except that the DC-SFQ converter 904 is replaced with a transduction SQUID 1304.

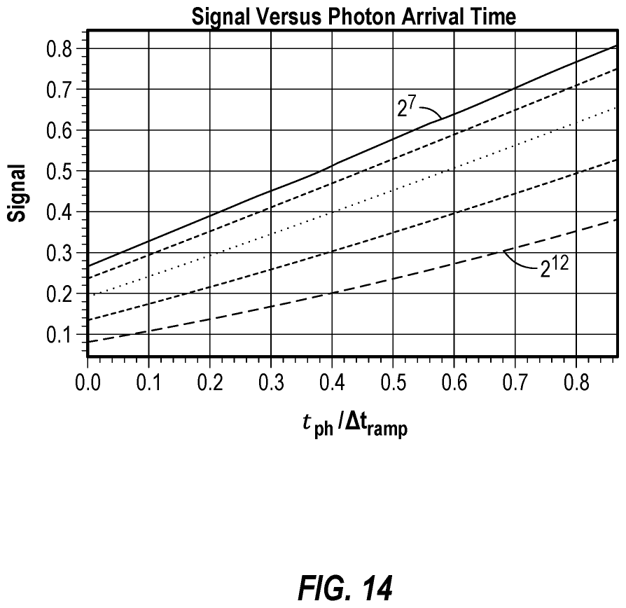

In addition, the current to this transduction SQUID is ramped on a clock with a period Δtᵣₐₘₚ. When a single photon 810 is detected, the bypass current I_{by} is coupled to the transduction SQUID 1304 via the magnetic flux Φₐ. After each clock cycle, the integrator current Iᵢ is measured. This integrator current Iᵢ is a nearly linear function of the arrival time tₚₕ of the single photon 810. FIG. 14 is a plot of signal size (i.e., Vₒᵤₜ) versus tₚₕ/Δtᵣₐₘₚ, as simulated for the superconducting circuit 1300 of FIG. 13.

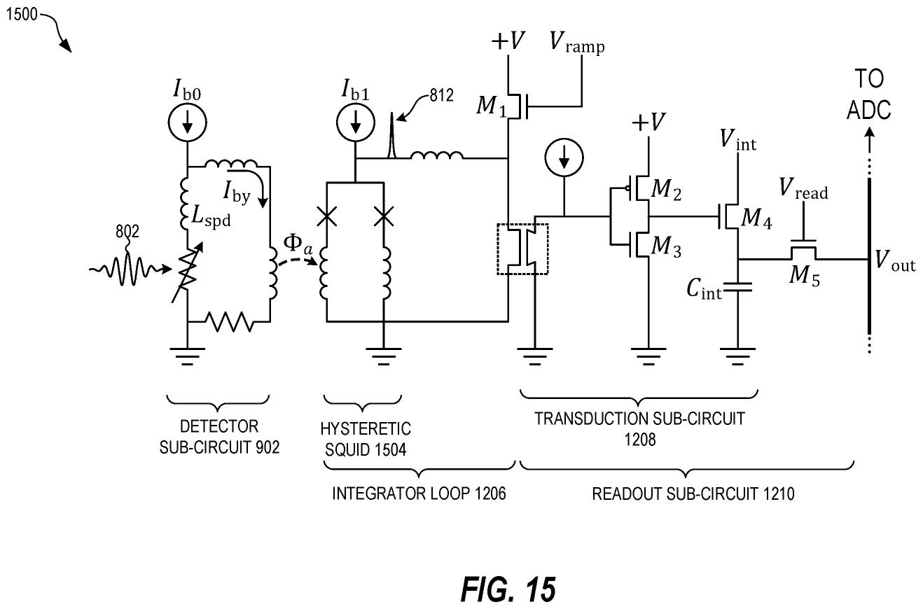

FIG. 15 is a schematic diagram of a superconducting circuit 1500 that both detects single photons and records their arrival times, in accordance with some of the present embodiments. The superconducting circuit 1500 uses the superconducting-circuit architecture 800 of FIG. 8. The superconducting circuit 1500 is similar to the superconducting circuit 1300 of FIG. 13 except that the transduction SQUID 1304 is designed to by hysteretic, i.e., the transduction SQUID 1304 of FIG. 13 is replaced by a hysteretic SQUID 1504. The SQUID 1504 is “hysteretic” in that when it is kicked above its critical current, the Josephson junctions continue to make fluxons until the current bias drops below a point lower than critical current. In this case, the bypass current I_{by} of the detector sub-circuit 902 will be high-pass filtered so that only the rising edge (couple hundred picoseconds) of the bypass current I_{by} couples to the hysteretic SQUID 1504. The hysteretic SQUID 1504 is biased with a constant current I_{b1} through the clock cycle, and it will add SFQ pulses 812 to the integrator loop 1206 from the time the SPD detects the single photon 810 until the current bias is turned off at the end of the clock cycle. In this way, the current in the integration loop is again a linear function of photon arrival time.

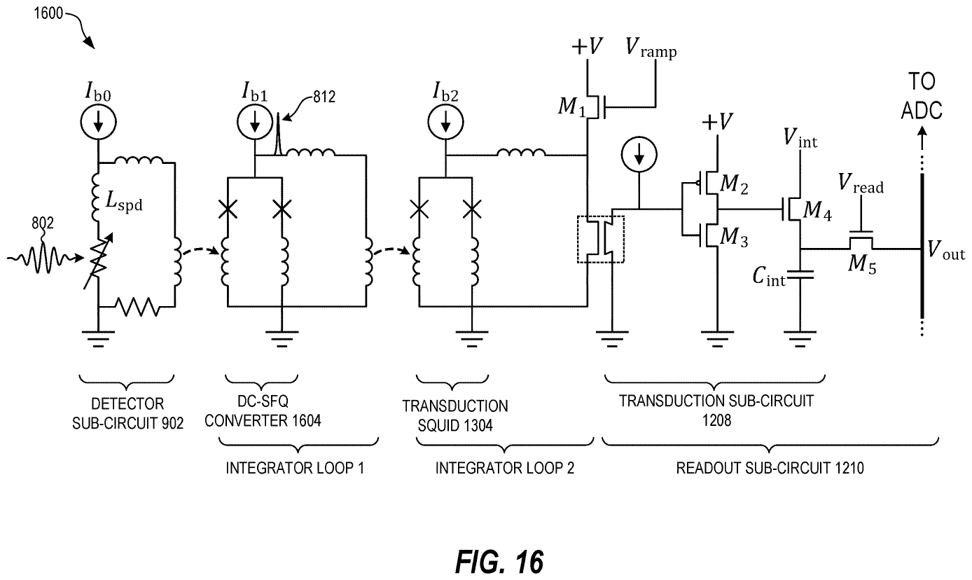

FIG. 16 is a schematic diagram of a superconducting circuit 1600 that both detects single photons and records their arrival times, in accordance with some of the present embodiments. The superconducting circuit 1600 uses the superconducting-circuit architecture 800 of FIG. 8. Unlike the superconducting circuits 1300 and 1500, the detector sub-circuit 902 now drives a DC-SFQ converter 1604 to produce exactly one SFQ pulse 812 per single photon. The DC-SFQ converter 1604 then drives the transduction SQUID 1304. In this use, the transduction SQUID 1304 need not be hysteretic because the signal from the DC-SFQ converter 1604 drives it at a constant level. However, the current in the DC-SFQ converter 1604 should be purged before it can be used again.

One application of the superconducting circuits 1300 (FIGS. 13), 1500 (FIG. 15), and 1600 (FIG. 16) is picosecond imaging circuit analysis (PICA). PICA is a technique for observing mid-infrared photons emitted from transistors when they switch. PICA registers the timing information of these photons to identify when transistors switch relative to each other and to the clock cycle. The superconducting circuits 1300, 1500, and 1600 advantageously store the timing information of single-photon detection events so that this timing information can be read out using CMOS circuitry nearly identical to that used to read out CMOS sensor arrays. This will allow us to scale the sensors up to megapixel arrays so that many millions of transistors can be monitored simultaneously.

### Combinations of Features

Features described above as well as those claimed below may be combined in various ways without departing from the scope hereof. The following examples illustrate possible, non-limiting combinations of features and embodiments described above. It should be clear that other changes and modifications may be made to the present embodiments without departing from the spirit and scope of this invention:
(A1) A superconducting circuit for detecting single photons includes a detector sub-circuit having a superconducting branch and a bypass branch in parallel with the superconducting branch. The superconducting branch includes a superconducting nanowire single-photon detector (SNSPD). The detector sub-circuit is configured to output a photon-indicating signal in response to the SNSPD absorbing a single photon. The superconducting circuit also includes a fluxon generator coupled to the bypass branch of the detector sub-circuit. The fluxon generator is configured to generate one or more single-flux quantum (SFQ) pulses in response to receiving the photon-indicating signal from the detector sub-circuit. The superconducting circuit also includes an integrator loop that includes the fluxon generator. The integrator loop is configured to increment an integrator current flowing through the integrator loop by an incremental current for each of the one or more SFQ pulses generated by the fluxon generator. The superconducting circuit also includes a readout sub-circuit configured to generate an output voltage that is based on the integrator current.
(A2) In the superconducting circuit denoted (A1), the fluxon generator is inductively coupled to the bypass branch of the detector sub-circuit.
(A3) In the superconducting circuit denote (A2), the bypass branch includes a primary inductor of a transformer; the detector sub-circuit is configured to generate, via the primary inductor and based on the photon-indicating signal, a magnetic flux in response to the SNSPD absorbing a single photon; the fluxon generator includes a secondary inductor of the transformer; and the fluxon generator is configured to generate the one or more SFQ pulses in response to receiving the magnetic flux from the detector sub-circuit via the secondary inductor.
(A4) In the superconducting circuit denoted (A1), the fluxon generator is electrically coupled to the bypass branch of the detector sub-circuit.
(A5) In any of the superconducting circuits denoted (A1) to (A4), the fluxon generator includes a direct-current (DC) superconducting quantum interference device (SQUID) configured to generate several SFQ pulses in response to receiving the photon-indicating signal from the detector sub-circuit.
(A6) In any of the superconducting circuits denoted (A1) to (A4), the fluxon generator includes a DC-to-single-flux-quantum (DC-SFQ) converter configured to generate only one SFQ pulse in response to receiving the photon-indicating signal from the detector sub-circuit.
(A7) In any of the superconducting circuits denoted (A1) to (A6), the integrator loop further includes a gate of a superconducting switch. The readout sub-circuit includes a channel of the superconducting switch.
(A8) In the superconducting circuit denoted (A7), the superconducting switch includes an hTron.
(A9) In either of the superconducting circuits denoted (A7) and (A8), the superconducting circuit further includes an inverter having an inverter input and an inverter output, the inverter input being electrically connected to the channel of the superconducting switch; a charging switch having a charging-switch gate, a charging-switch drain, and a charging-switch source, the charging-switch gate being electrically connected to the inverter output; and a charging capacitor electrically connected to a charging-switch drain.
(A10) In the superconducting circuit denoted (A9), the inverter includes an n-channel field-effect transistor and a p-channel field-effect transistor. Furthermore, the charging switch includes a field-effect transistor.
(A11) In either of the superconducting circuits denoted (A9) and (A10), the superconducting circuit further includes an output switch configured to electrically connect the charging capacitor to a bus.
(A12) In the superconducting circuit denoted (A11), the output switch includes a field-effect transistor.
(A13) In any of the superconducting circuits denoted (A7) to (A12), the superconducting circuit further includes a ramp switch having a ramp-switch gate, a ramp-switch source, and a ramp-switch drain. The ramp-switch source is electrically connected to the gate of the superconducting switch.
(A14) In the superconducting circuit denoted (A13), the ramp switch includes a field-effect transistor.
(A15) In any of the superconducting circuits denoted (A1) to (A14), the readout sub-circuit includes a DC SQUID that is inductively coupled to the integrator loop.
(A16) In any of the superconducting circuits denoted (A1) to (A15), the superconducting circuit further includes a Josephson transmission line electrically connecting between the fluxon generator and the integrator loop.
(A17) In any of the superconducting circuits denoted (A1) to (A16), the integrator loop is a first integrator loop. The superconducting circuit further includes a transduction SQUID inductively coupled to the first integrator loop. The superconducting circuit also includes a second integrator loop that includes the transduction SQUID.
(B1) A method for detecting single photons includes absorbing a single photon with a SNSPD located in a superconducting branch of a detector sub-circuit. The method also includes diverting, in response to said absorbing, a bias current from the superconducting branch to a bypass branch of the detector sub-circuit. The method also includes coupling a photon-indicating signal from the bypass branch to a fluxon generator, the photon-indicating signal being based on the diverted bias current. The method also includes generating, with the fluxon generator, one or more SFQ pulses in response to the photon-indicating signal. The method also includes incrementing, by an incremental current for each of the one or more SFQ pulses, an integrator current flowing through an integrator loop that includes the fluxon generator. The method also includes generating an output voltage that is based on the integrator current.
(B2) In the method denoted (B1), the fluxon generator is a DC SQUID. Said generating includes generating several SFQ pulses in response to the photon-indicating signal.
(B3) In the method denoted (B1), the fluxon generator is a DC-SFQ converter. Said generating includes generating only one SFQ pulse in response to the photon-indicating signal.
(B4) In any of the methods denoted (B1) to (B3), the method further includes driving a gate of a superconducting switch with the integrator current, the integrator loop including the gate of the superconducting switch.
(B5) In the method denoted (B4), said driving the gate of the superconducting switch changes a voltage level of an output signal of the superconducting switch.
(B6) In the method denoted (B5), the method further includes inverting the voltage level of the output signal to generate an inverted signal.
(B7) In the method denoted (B6), the method further includes driving a charging switch with the inverted signal to charge a charging capacitor.
(B8) In the method denoted (B7), said generating the output voltage includes outputting a voltage of the charging capacitor.
(B9) In the method denoted (B8), said outputting the voltage of the charging capacitor includes driving an output switch to electrically connect the charging capacitor to a bus.
(B10) In any of the methods denoted (B4) to (B9), said driving the gate of the superconducting switch comprises driving the gate of the superconducting switch with a ramped current that is injected into the integrator loop.
(B11) In any of the methods denoted (B1) to (B10), said coupling includes inductively coupling.
(B12) In any of the methods denoted (B1) to (B10), said coupling includes electrically coupling.

Changes may be made in the above methods and systems without departing from the scope hereof. It should thus be noted that the matter contained in the above description or shown in the accompanying drawings should be interpreted as illustrative and not in a limiting sense. The following claims are intended to cover all generic and specific features described herein, as well as all statements of the scope of the present method and system, which, as a matter of language, might be said to fall therebetween.

1. A superconducting circuit for detecting single photons, comprising:
a detector sub-circuit comprising:
a superconducting branch including a superconducting nanowire single-photon detector (SNSPD); and
a bypass branch in parallel with the superconducting branch;
the detector sub-circuit being configured to output a photon-indicating signal in response to the SNSPD absorbing a single photon;
a fluxon generator coupled to the bypass branch of the detector sub-circuit, the fluxon generator being configured to generate one or more single-flux quantum (SFQ) pulses in response to receiving the photon-indicating signal from the detector sub-circuit;
an integrator loop comprising the fluxon generator, the integrator loop being configured to increment an integrator current flowing through the integrator loop by an incremental current for each of the one or more SFQ pulses generated by the fluxon generator; and
a readout sub-circuit configured to generate an output voltage that is based on the integrator current.

2. The superconducting circuit of claim 1, the fluxon generator being inductively coupled to the bypass branch of the detector sub-circuit.

3. (canceled)

4. The superconducting circuit of claim 1, the fluxon generator being electrically coupled to the bypass branch of the detector sub-circuit.

5. The superconducting circuit of claim 1, the fluxon generator comprising a direct-current (DC) superconducting quantum interference device (SQUID) configured to generate several SFQ pulses in response to receiving the photon-indicating signal from the detector sub-circuit.

6. The superconducting circuit of claim 1, the fluxon generator comprising a DC-to-single-flux-quantum (DC-SFQ) converter configured to generate only one SFQ pulse in response to receiving the photon-indicating signal from the detector sub-circuit.

7. The superconducting circuit of claim 1, wherein:
the integrator loop further comprises a gate of a superconducting switch; and
the readout sub-circuit comprises a channel of the superconducting switch.

8. (canceled)

9. The superconducting circuit of claim 7, further comprising:
an inverter having an inverter input and an inverter output, the inverter input being electrically connected to the channel of the superconducting switch;
a charging switch having a charging-switch gate, a charging-switch drain, and a charging-switch source, the charging-switch gate being electrically connected to the inverter output; and
a charging capacitor electrically connected to a charging-switch drain.

10. The superconducting circuit of claim 9, wherein:
the inverter comprises an n-channel field-effect transistor and a p-channel field-effect transistor; and
the charging switch comprises a field-effect transistor.

11-12. (canceled)

13. The superconducting circuit of claim 7, further comprising a ramp switch having a ramp-switch gate, a ramp-switch source, and a ramp-switch drain, the ramp-switch source being electrically connected to the gate of the superconducting switch.

14. (canceled)

15. The superconducting circuit of claim 1, the readout sub-circuit comprising a DC SQUID that is inductively coupled to the integrator loop.

16. (canceled)

17. The superconducting circuit of claim 1, wherein:
the integrator loop is a first integrator loop; and
the superconducting circuit further comprises:
a transduction SQUID inductively coupled to the first integrator loop; and
a second integrator loop comprising the transduction SQUID.

18. A method for detecting single photons, comprising:
absorbing a single photon with a SNSPD located in a superconducting branch of a detector sub-circuit;
diverting, in response to said absorbing, a bias current from the superconducting branch to a bypass branch of the detector sub-circuit;
coupling a photon-indicating signal from the bypass branch to a fluxon generator, the photon-indicating signal being based on the diverted bias current;
generating, with the fluxon generator, one or more SFQ pulses in response to the photon-indicating signal;
incrementing, by an incremental current for each of the one or more SFQ pulses, an integrator current flowing through an integrator loop that includes the fluxon generator; and
generating an output voltage that is based on the integrator current.

19. The method of claim 18, wherein:
the fluxon generator is a DC SQUID; and
generating comprises generating several SFQ pulses in response to the photon-indicating signal.

20. The method of claim 18, wherein:
the fluxon generator is a DC-SFQ converter; and
generating comprises generating only one SFQ pulse in response to the photon-indicating signal.

21. The method of claim 18, further comprising driving a gate of a superconducting switch with the integrator current, the integrator loop including the gate of the superconducting switch.

22. The method of claim 21, wherein driving the gate of the superconducting switch changes a voltage level of an output signal of the superconducting switch.

23. The method of claim 22, further comprising inverting the voltage level of the output signal to generate an inverted signal.

24. The method of claim 23, further comprising driving a charging switch with the inverted signal to charge a charging capacitor.

25. The method of claim 24, wherein generating the output voltage comprises outputting a voltage of the charging capacitor.

26. (canceled)

27. The method of claim 21, wherein driving the gate of the superconducting switch comprises driving the gate of the superconducting switch with a ramped current that is injected into the integrator loop.

28-29. (canceled)
